(19) United States
(12) Patent Application Publication
(10) Pub. No.: US 2011/0179337 A1
(43) Pub. Date: Jul. 21, 2011

(54) MEMORY UTILIZATION METHOD FOR LOW DENSITY PARITY CHECK CODE, LOW DENSITY PARITY CHECK CODE DECODING METHOD AND DECODING APPARATUS THEREOF

(75) Inventors: Mu-Chung Chen, Taipei County (TW); Chiu-Tien Wu, Changhua County (TW)

(73) Assignee: SUNPLUS TECHNOLOGY CO., LTD., Hsinchu (TW)

(21) Appl. No.: 12/769,616

(22) Filed: Apr. 28, 2010

(30) Foreign Application Priority Data
Jan. 20, 2010 (TW) 99101523

(51) Int. Cl. H03M 13/05; G06F 11/10

(52) U.S. Cl. 714/763; 714/E11.034

(57) ABSTRACT

A memory utilization method of low density parity check code (LDPC), a LDPC decoding method and a decoding apparatus thereof are provided, applicable for a decoding process in a wireless receiver. The memory utilization method of LDPC includes the following steps. First, variable node processes (VNPs) or check node processes (CNPs) required to be executed at a same time stage are determined. Next, the VNPs or the CNPs executed at the same time stage are allocated in different VNP groups or different CNP groups. Further, a folding factor of memory units is determined according to a desired data throughput. Then, according to the folding factor and the allocated VNP groups or the allocated CNP groups, the memory units are connected serially as a plurality of parallel processing memory modules.

### CROSS-REFERENCE TO RELATED APPLICATION

This application claims the priority benefit of Taiwan application serial no. 99101523, filed on Jan. 20, 2010. The entirety of the above-mentioned patent application is hereby incorporated by reference herein and made a part of this specification.

### BACKGROUND

1. Technical Field

The invention relates to a memory utilization method of low density parity check code (LDPC). More particularly, the invention relates to a memory utilization method of LDPC, an LDPC decoding method and a decoding apparatus thereof.

2. Description of Related Art

Presently, low density parity check code (LDPC) is gradually used in wireless communication technology, and the LDPC has a better performance than a current widely used turbo code. For example, in a digital video broadcasting second generation (DVB-S2) standard developed by European telecommunications standards institute (ETSI), the LDPC is widely used for channel coding.

Although the LDPC has better channel error detection and error correction capabilities for the channel coding, a decoding process of the LDPC is performed according to a soft-decision method, which generally requires repeatedly cyclic computations to obtain a decoding result. Moreover, since the LDPC decoding process requires a parity check matrix with a relatively large size to assist the decoding computation, a memory module with a relatively large volume has to be used to implement the decoding process. Therefore, in an integrated circuit of an LDPC decoding apparatus, the memory module generally occupies most of a chip space.

U.S. Patent Publication No. 2008/0104474A1 discloses a conventional LDPC decoding method and a decoding apparatus, in which a computation method of using variable node processes (VNPs) and check node processes (CNPs) to implement the decoding process is provided, and a bipartite graph (or tanner graph) is used to connect the VNPs and the CNPs with corresponding temporary storage memory units.

FIG. 1A is a schematic diagram illustrating a parity check matrix 110, and FIG. 1B is a schematic diagram illustrating a relationship between variable nodes and check nodes in the parity check matrix 110. As shown in FIG. 1A, the seven columns of the parity check matrix 110 respectively correspond to variable nodes x₁, x₂, x₃, x₄, x₅, x₆ and x₇, and three rows of the parity check matrix 110 respectively correspond to check nodes c₁, c₂ and c₃. In the LDPC decoding process, a matrix multiplication is performed to related probability information of the LDPC and the parity check matrix 110 to obtain the decoding result. Actually, the LDPC decoding apparatus temporarily stores the probability information in memory units corresponding to positions “1” in the parity check matrix 110, and then the variable nodes and the check nodes alternately perform computations to the probability information.

As shown in FIG. 1B, when there is a connection between the variable node and the check node in the parity check matrix 110, the variable node and the check node can alternately perform the computations. After the computations of the variable nodes and the check nodes having corresponding relations (having connections in FIG. 1B) are completed, respective computation results are stored in the same memory unit or the same memory position. A computation cycle is completed only after the variable node and the check node alternately complete the computations. If there is no connection between the variable node and the check node in the parity check matrix 110, none computation is performed. The more the computation cycles are, the closer the obtained LDPC decoding result approaches a correct result.

FIG. 1C is a schematic diagram illustrating a memory structure 130 of an LDPC decoding apparatus. The memory structure 130 is a partially parallel processing structure. In FIG. 1C, memory units 132, 134, 136 and 138 are all the same, and the memory structure 130 corresponds to a parity check matrix of the LDPC, and has at least (m+1)×(n+1) memory units. The connection between each of the memory units and the other memory unit or the connection between the memory unit and the VNP process or the CNP process further includes at least a clock port Clock, a data port Data, an address port Addr, a write enable port Wren and a data output port Q. Therefore, in the LDPC decoding process, especially when the parity check matrix with a relatively great size is used to assist the decoding process, the memory structure 130 with the partially parallel processing structure obviously has a routing congestion problem. For example, the DVB-S2 standard requires 64,800 blocks to perform the decoding process. If each data is represented by 6 bits, the 64,800 blocks totally have 1.7 million bits required to be temporarily stored in the memory module. Although the memory modules of the memory structure 130 corresponding to the parity check matrix can be divided into memory units with relatively small sizes to perform the computation, when a number of the memory units becomes huge (for example, several millions of memory units), spaces between adjacent memory units become smaller. Even if the spaces between the memory units are enlarged for resolving the routing congestion problem, a routing complexity is still relatively high (due to connection relationships between the memory units and a VNP module and a CNP module), and the memory size is relatively large consequently.

In another conventional LDPC decoding method or decoding apparatus, the memory units corresponding to the same VNP or the same CNP are serially connected in different groups. During the LDPC decoding process, the computation is performed on each of the groups through serially reading/writing data in the memory units. However, such a decoding apparatus or decoding method in collaboration with the VNPs or the CNPs for serially reading/writing data can only resolve the routing congestion problem or reduce the routing complexity, and a decoding computation speed thereof is still too slow, thereby reducing overall data throughput.

### SUMMARY

The invention is directed to a memory utilization method of low density parity check code (LDPC), a LDPC decoding method and a decoding apparatus thereof.

The invention provides a memory utilization method of LDPC, which is adapted to a decoding process in a wireless receiver. The memory utilization method of LDPC includes the following steps. Variable node processes (VNPs) or check node processes (CNPs) required to be executed at a same time stage are determined. Besides, the VNPs or the CNPs executed at the same time stage are allocated in different VNP groups or different CNP groups. Further, a folding factor of memory units is determined according to a desired data throughput. Moreover, the memory units are connected serially as a plurality of parallel processing memory modules according to the folding factor and the allocated VNP groups or the allocated CNP groups.

The invention provides a low density parity check code (LDPC) decoding method, which is adapted to a decoding process in a wireless receiver. The LDPC decoding method includes the following steps. VNPs or CNPs are executed on probability information in a first memory module and a second memory module. Besides, it is determined whether the probability information in the first memory module and the second memory module satisfies a decoding termination condition. Moreover, after the probability information of the first memory module is converted into an LDPC output data through a hard decision, the LDPC output data is reordered in the second memory module.

The invention provides a low density parity check code (LDPC) decoding apparatus, which is adapted to a decoding process in a wireless receiver. The LDPC decoding apparatus includes a variable node process (VNP) module, a check node process (CNP) module, a computation termination determination module and a slicer. The VNP module is configured to execute a VNP on probability information in a first memory module and a second memory module. The CNP module is configured to execute executing a CNP on the probability information in the first memory module and the second memory module. The computation termination determination module is configured to determine whether the probability information in the first memory module and the second memory module satisfies a decoding termination condition. The slicer is configured to convert the probability information of the first memory module into an LDPC output data through a hard decision, and reorder the LDPC output data through the second memory module.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic diagram illustrating a parity check matrix.

FIG. 1B is a schematic diagram illustrating a relationship between variable nodes and check nodes in a parity check matrix.

FIG. 1C is a schematic diagram illustrating a memory structure of an LDPC decoding apparatus.

FIG. 2 is a system block diagram illustrating an LDPC decoding apparatus according to an exemplary embodiment of the invention.

FIG. 3A is a schematic diagram illustrating a parity check matrix according to an exemplary embodiment of the invention.

FIG. 3B is a schematic diagram illustrating a sub-matrix according to an exemplary embodiment of the invention.

FIG. 3C is a schematic diagram illustrating reordering of a parity check matrix according to an exemplary embodiment of the invention.

FIG. 3D is a schematic diagram illustrating grouping of a parity check matrix according to another exemplary embodiment of the invention.

FIG. 4 is a schematic diagram illustrating a modified partially parallel processing memory structure according to an exemplary embodiment of the invention.

FIG. 5 is a flowchart illustrating a memory utilization method of LDPC according to an exemplary embodiment of the invention.

FIG. 6 is a flowchart illustrating an LDPC decoding method according to an exemplary embodiment of the invention.

FIG. 7 is a system block diagram illustrating another LDPC decoding apparatus according to another exemplary embodiment of the invention.

### DESCRIPTION OF THE EMBODIMENTS

Reference will now be made in detail to the exemplary embodiments of the invention, examples of which are illustrated in the accompanying drawings. Wherever possible, the same reference numbers are used in the drawings and the description to refer to the same or like parts.

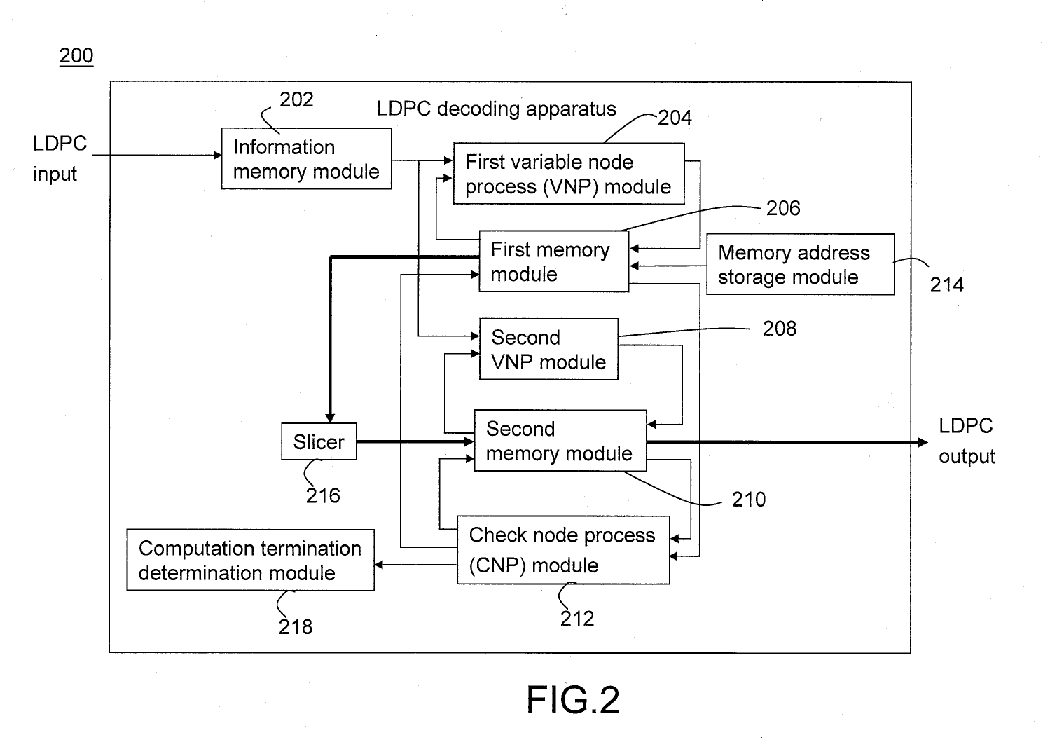

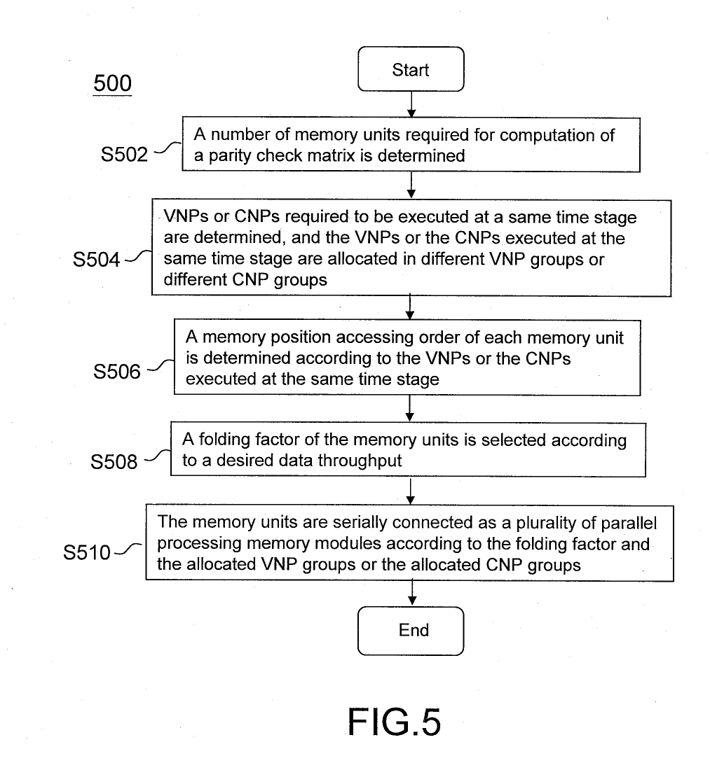

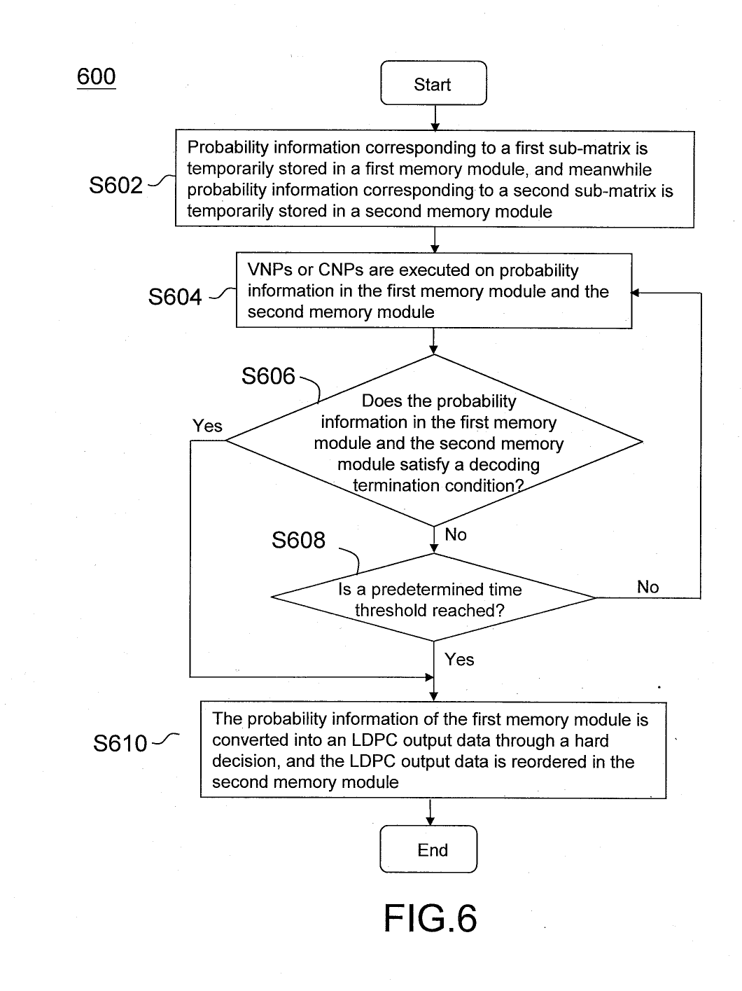

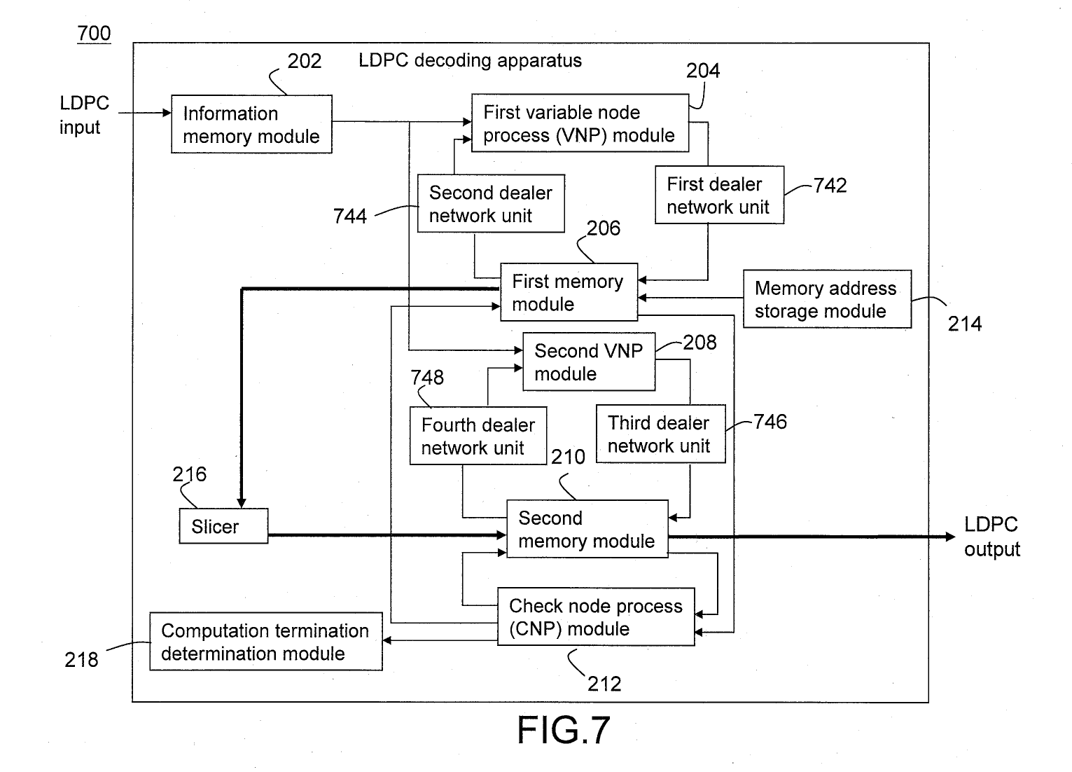

The invention provides a memory utilization method of low density parity check code (LDPC), an LDPC decoding method and a decoding apparatus thereof. The memory utilization method of LDPC is used in an LDPC decoding process. In the following descriptions, an LDPC decoding apparatus 200 and an LDPC decoding apparatus 200 are introduced in accordance with FIG. 2 and FIG. 7, the memory utilization method of LDPC is introduced in accordance with FIG. 5, and the LDPC decoding method is introduced in accordance with FIG. 6.

FIG. 2 is a system block diagram illustrating the LDPC decoding apparatus 200 according to an exemplary embodiment of the invention. The LDPC decoding apparatus 200 can be configured in a wireless receiver, for example, a digital video broadcasting second generation (DVB-S2) standard receiver. In the exemplary embodiment, the LDPC decoding apparatus 200 includes at least an information memory module 202, a first variable node process (VNP) module 204, a first memory module 206, a second VNP module 208, a second memory module 210, a check node process (CNP) module 212, a memory address storage module 214, a slicer 216, a computation termination determination module 218 and a control module 220 (not shown).

In the exemplary embodiment, the memory modules such as the first memory module 206 and the second memory module 210 can be configured to store a program module. When the program module is executed by the processing modules (for example, the first VNP module 204, the second VNP module 208 and the CNP module 212), one or a plurality of processes are executed to generate a media program. Moreover, the first memory module 206 and the second memory module 210 can be one or a plurality of memory devices, which are configured for storing data, computation results or probability information. In an exemplary embodiment of the invention, the memory devices of the first memory module 206 and the second memory module 210 can include one of a magnetic storage device, an optical storage device, a static random access memory (SRAM), a phase change memory (PCM) and a flash memory device or combinations thereof Moreover, in other embodiments of the invention, the first memory module 206 and the second memory module 210 can be integrated into one memory module. In the exemplary embodiment, the first VNP module 204, the second VNP module 208 and the CNP module 212 can respectively include a plurality of processing units, processing devices or processing chips.

Referring to FIG. 2, in the present exemplary embodiment, the control module 220 is electrically connected to the information memory module 202, the first VNP module 204, the first memory module 206, the second VNP module 208, the second memory module 210, the CNP module 212, the memory address storage module 214, the slicer 216 and the computation termination determination module 218. Moreover, the control module 220 is configured to control start and end of an external input process (for example, receiving an LDPC input), start and end of an external output process (for example, outputting an LDPC output) of the whole LDPC decoding apparatus 200, and controlling signal transmissions among the aforementioned modules, or controlling start and end of the respective computation process of each of the modules.

Referring to FIG. 2, the information memory module 202 is configured to temporarily store probability information provided to the LDPC decoding apparatus 200 from a demodulator of a previous stage, and the probability information is generally converted into a pattern of a log-likelihood ratio (LLR) to facilitate subsequent computations. The LDPC decoding apparatus 200 is required to complete the LDPC decoding process within a fixed period or a predetermined time threshold, for example, a frame duration. In another embodiment of the invention, the first VNP module 204 and the second VNP module 208 can be integrated into a same node processing module.

In the present embodiment, in order to clearly describe the operation principle, the first VNP module 204 and the second VNP module 208 are separately illustrated, though operations of the first VNP module 204 and the second VNP module 208 can be synchronous and independent or can be collaborative. The first VNP module 204 and the second VNP module 208 are coupled to the information memory module 202, and are respectively connected to the first memory module 206 and the second memory module 210 for respectively storing the probability information in the information memory module 202 to the first memory module 206 and the second memory module 210. Moreover, the probability information corresponds to the positions having values of “1” in a parity check matrix.

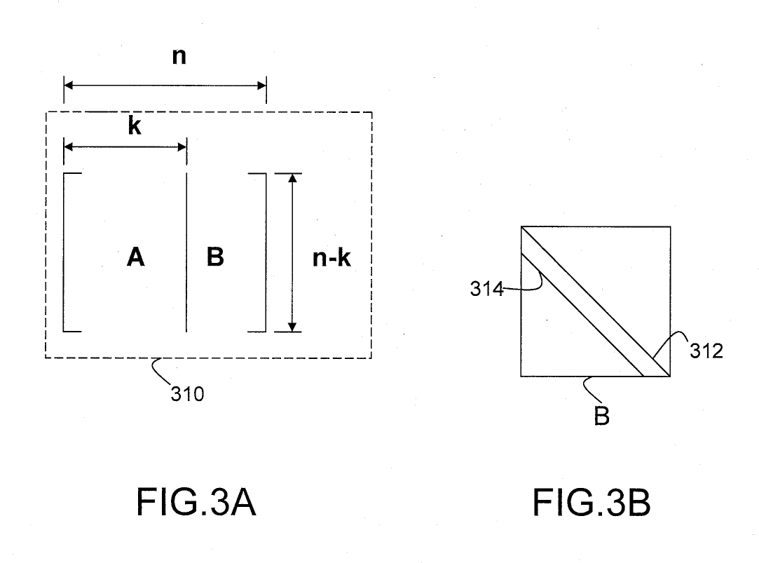

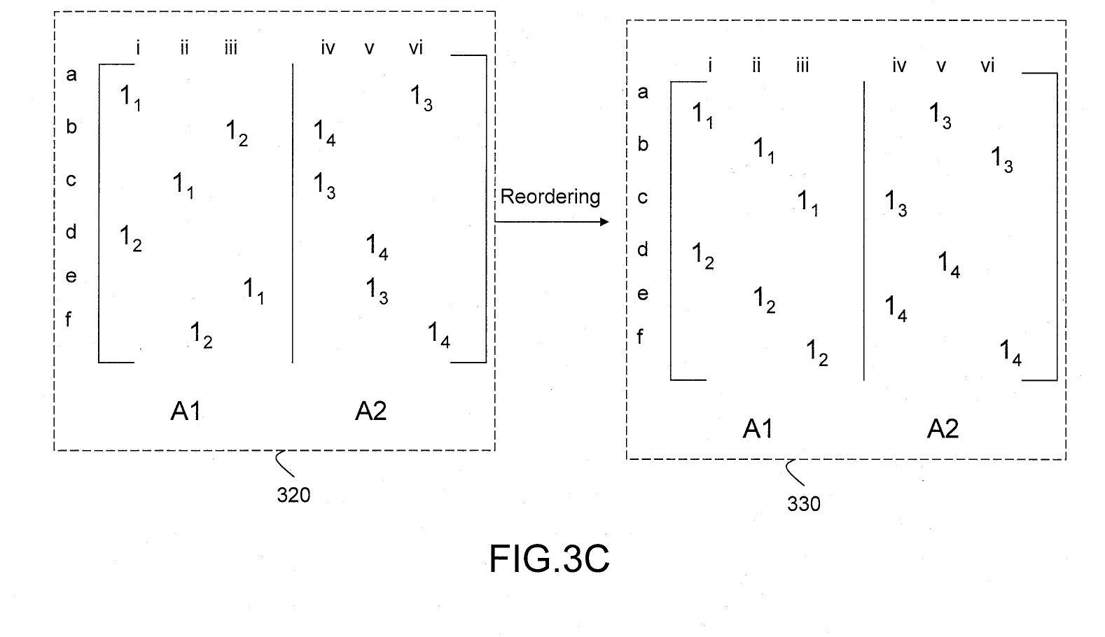

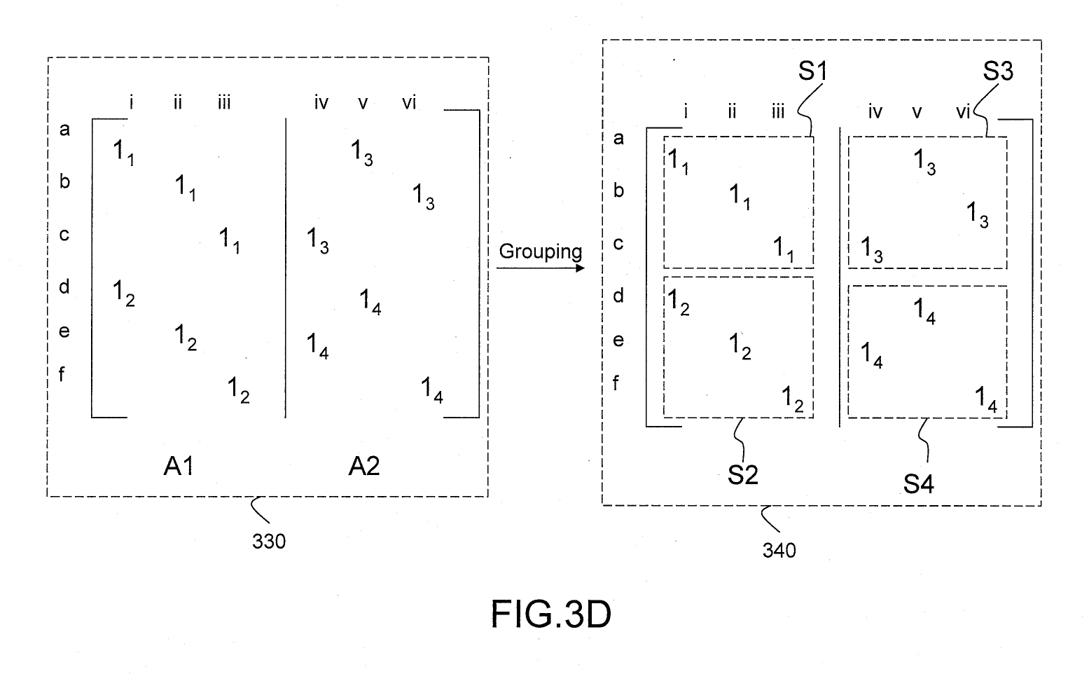

FIG. 3A is a schematic diagram illustrating a parity check matrix 310 according to an exemplary embodiment of the invention. A size of a parity check matrix H (i.e., the parity check matrix 310 of FIG. 3) is n×(n−k), wherein n>k, and n and k are positive integers. When the parity check matrix H is applied to the LDPC decoding process, it generally has a characteristic of being irregular repeat accumulate (IRA), i.e., an IRA-LDPC. In other embodiment of the inventions, the parity check matrix H can also have a characteristic of being quasi-cyclic (QC), i.e., a QC-LDPC. During an actual LDPC decoding process, to facilitate the decoding process, the parity check matrix H can be divided into a sub-matrix A and a sub-matrix B. As shown in FIG. 3A, a size of the sub-matrix A is k×(n−k), and a size of the sub-matrix B is (n−k)×(n−k). Moreover, distribution of “1” in the sub matrix A is relatively irregular, and distribution of “1” in the sub matrix B is regular. FIG. 3B is a schematic diagram illustrating a sub-matrix B according to an exemplary embodiment of the invention. The sub matrix B is a square matrix, and is a special identity matrix having diagonals 312 and 314 of all “1”, wherein there is a fixed offset between the diagonals 312 and 314.

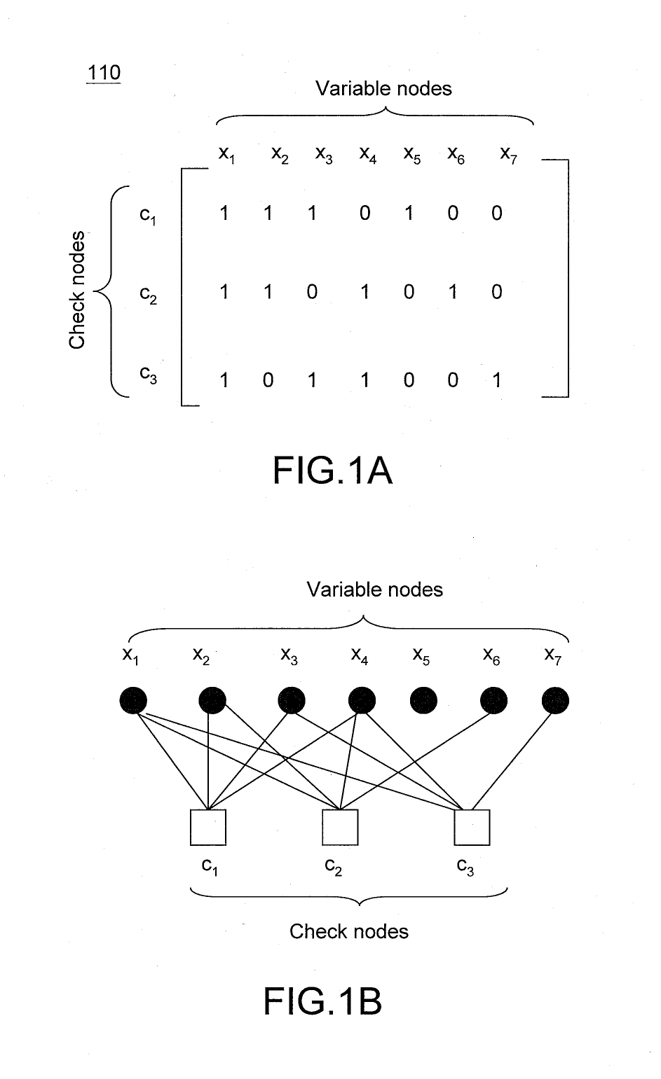

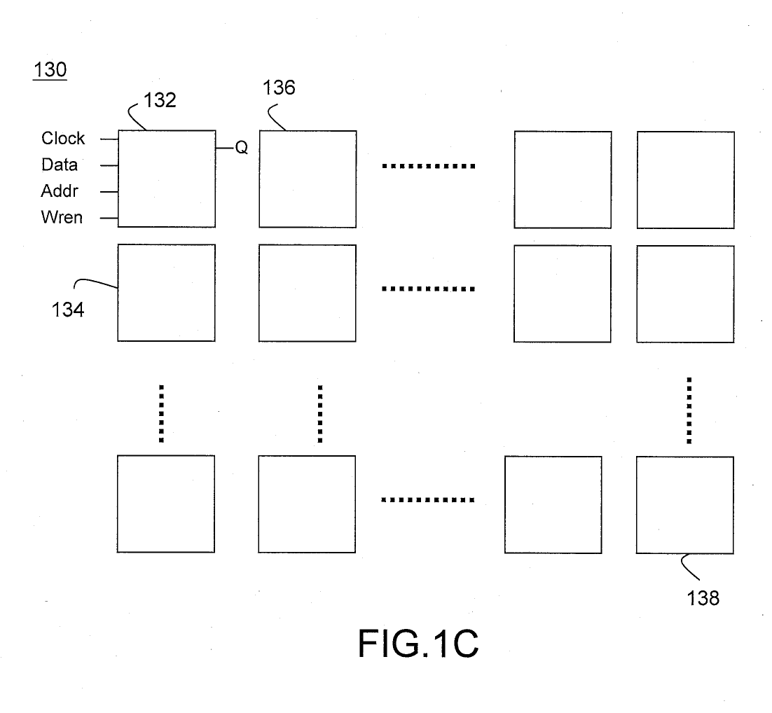

Referring to FIG. 2 and FIG. 3A, the first VNP module 204 temporarily stores the probability information corresponding to the sub-matrix A into the first memory module 206, and the second VNP module 208 temporarily stores the probability information corresponding to the sub-matrix B into the second memory module 210. Moreover, the CNP module 212 is electrically connected to the first memory module 206 and the second memory module 210. The first VNP module 204 and the CNP module 212 alternately perform computations on the probability information of the first memory module 206, and the computations are alternately performed according to a corresponding relationship similar to that (the connection relationship in FIG. 1B) of the variable nodes and the check nodes of FIG. 1B. After the respective computations of the first VNP module 204 and the CNP module 212 are completed, respective computation results thereof are temporarily stored in a same memory position in the first memory module 206, and a computation cycle is just completed after the first VNP module 204 and the CNP module 212 alternately complete one computation. Similarly, the second VNP module 208 and the CNP module 212 alternately perform computations on the probability information of the second memory module 210. After the respective computations of the second VNP module 208 and the CNP module 212 are completed, respective computation results thereof are temporarily stored in a same memory position in the second memory module 210, and a computation cycle is just completed after the second VNP module 208 and the CNP module 212 alternately complete one computation.

Referring to FIG. 2, the CNP module 212 is further coupled to the computation termination determination module 218. When each computation cycle is completed, the CNP module 212 transmits the probability information of the first memory module 206 and the second memory module 210 to the computation termination determination module 218, and the computation termination determination module 218 determines whether the obtained probability information satisfies a condition of a following equation (1):

νH^{T}=0 equation (1)

Where, ν is a vector, which represents the LDPC input received by the LDPC decoding apparatus 200, i.e., an LDPC codeword received via a wireless transmission, and H^{T} represents a transpose matrix of the parity check matrix H.

If the probability information in the first memory module 206 and the second memory module 210 satisfies the above equation (1), the computation termination determination module 218 notifies the first VNP module 204, the second VNP module 208 and the CNP module 212 through the control module 220 to terminate the current computations. Now, the slicer 216 stores the probability information corresponding to the sub-matrix A in the first memory module 206 into the second memory module 210, i.e., overwrites a content of the second memory module 210. After the probability information in the first memory module 206 is converted into the LDPC output through a hard decision, the LDPC output is reordered or re-organized in the second memory module 210, and then the second memory module 210 outputs the LDPC output. The slicer 216 is electrically connected to the first memory module 206 and the second memory module 210, and when the slicer 216 stores the probability information corresponding to the sub-matrix A in the first memory module 206 into the second memory module 210, it performs the hard decision to the probability information corresponding to the sub-matrix A, so as to generate a decoding result. After the re-ordering or the re-organization, a bit sequence of the generated LDPC output corresponds to a bit sequence of the LDPC input received by the LDPC decoding apparatus 200. During a stage of outputting the LDPC output, the probability information corresponding to the sub-matrix B is regarded as redundant, which is also a characteristic of a block code. Therefore, in the exemplary embodiment, the second memory module 210 is configured to reorder or re-organize the decoding result at the stage of outputting the LDPC output.

If time spent by the first VNP module 204, the second VNP module 208 and the CNP module 212 exceeds a predetermined time threshold, for example, the control module 220 confirms that the above time reaches the predetermined time threshold, the control module 220 terminates the current computations of the first VNP module 204, the second VNP module 208 and the CNP module 212. The predetermined time threshold can be configured as one frame duration. Then, the control module 220 notifies the slicer 216 to convert the probability information in the first memory module 206 into the LDPC output through the hard decision, and stores the LDPC output into the second memory module 210 for reordering or re-organization, and then the second memory module 210 outputs the LDPC output.

If the probability information in the first memory module 206 and the second memory module 210 does not satisfy the condition of the above equation (1), and the time spent for the current computations does not exceed the time threshold, the first VNP module 204, the second VNP module 208 and the CNP module 212 continually carry on a next computation cycle. Moreover, the memory address storage module 214 is coupled to the first memory module 206, and when the CNP module 212 executes the CNP on the probability information of the first memory module 206, the memory address storage module 214 provides a suitable memory address to the CNP module 212 to ensure reading or writing a correct memory position.

FIG. 3C is a schematic diagram illustrating reordering of a sub-matrix A according to an exemplary embodiment of the invention. Assuming the sub-matrix A (i.e. a sub matrix 320) is a part of an IRA-LDPC matrix, and includes a plurality of shifted and offset identity matrices with smaller sizes (or the sub-matrix A is divided into sub-matrices A1 and A2), wherein each identity matrix has randomly repeated patterns. The LDPC decoding apparatus 200 can also include a matrix converting unit 230 (not shown), which is configured for reordering and converting the sub-matrix A (including columns i, ii, iii, iv, v, vi and rows a, b, c, d, e, f) into a sub-matrix A′ which is a part of another QC-LDPC matrix.

FIG. 3D is a schematic diagram illustrating grouping of a sub-matrix A according to another exemplary embodiment of the invention. It is Assumed herein that the matrix converting unit 230 can further group the sub-matrix A′ into four identity matrices (blocks) S1, S2, S3 and S4 shown in FIG. 3D. From another point of view, the identity matrices S1, S2, S3 and S4 can be stored by independent memory units, and the first VNP module 204 and the CNP module 212 can respectively access the memory units corresponding to the identity matrices S1, S2, S3 and S4, so as to execute the VNPs or the CNPs. However, grouping of the sub-matrix A′ shown in FIG. 3D just serves as an example, and during an actual LDPC decoding process, the sub-matrix A′ can be grouped into smaller identity matrices other than a size of 3×3, and a number of the required memory units corresponding to the sub-matrix A or the sub-matrix A′ can be tens of thousands or hundreds of thousands. Moreover, to reduce a hardware cost of the LDPC decoding apparatus 200, and under a principle of maintaining parallel processing memory units, a number of the processing units is not equal to the number of the memory units. Therefore, the processing units in the first VNP module 204, the second VNP module 208 and the CNP module 212 can just process the probability information of a part of the memory units at a same time stage. Therefore, a time required for the whole LDPC decoding process is increased, though the whole hardware cost and a circuit area are suitably reduced.

To reduce a routing number and a routing complexity among the memory units, or reduce the routing complexity between the memory units and the other peripheral devices, for example, between the memory units the first VNP module 204, the second VNP module 208 and the CNP module 212, and maintain the partially parallel processing principle, in the exemplary embodiment, the parity check matrix required in the LDPC decoding process is divided into a first sub-matrix (i.e. a sub-matrix A) and a second sub-matrix (i.e. a sub-matrix B). Moreover, the first memory module 206 corresponding to the first sub-matrix A applies a modified partially parallel processing structure. Namely, the memory units in the first memory module 206 are suitably grouped and connected in series, so as to reduce overall occupation area of the memory device. In this way, the routing complexity among the memory units and between the memory units and the peripheral devices can be simultaneously reduced. Moreover, the second memory unit 210 corresponding to the second sub-matrix B is configured to perform the decoding computation or configured to reorder the decoding result of the probability information of the first memory module 206 in different time stages.

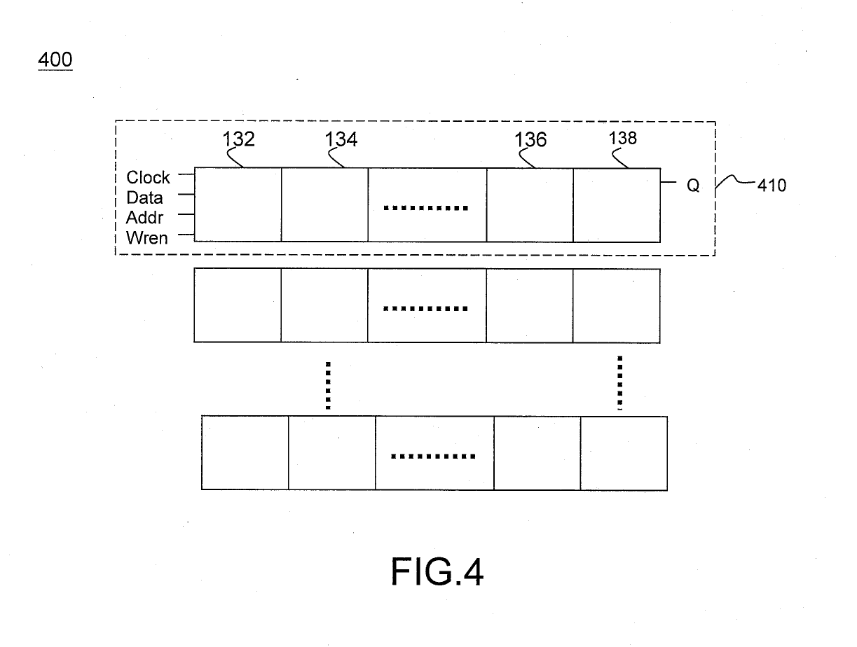

FIG. 4 is a schematic diagram illustrating a modified partially parallel processing memory structure 400 according to an exemplary embodiment of the invention. The memory structure 400 can be used in the first memory module 206. In the memory structure 400, the memory units shown in FIG. 1C are suitably grouped, and the memory units grouped into the same group are serially connected. Therefore, each of the serially connected memory device (for example, the memory device 410 formed by serially connecting the memory units 132, 134, 136 and 138) just has one input port set, which includes, for example, a clock port Clock, a data port Data, an address port Addr and a write enable port Wren. Moreover, each of the serially connected memory device has just one output port set, which includes at least one data output port Q. In this way, a port number of the memory units is greatly reduced, so that the routing number and routing complexity among the memory units are reduced, and extra overhead is reduced. After the memory structure 400 is introduced, a function of the memory address storage module 214 is further described with reference of FIG. 3C, FIG. 3D and FIG. 4.

The first VNP module 204 and the CNP module 212 alternately process the probability information of the first memory module 206, and the second VNP module 208 and the CNP module 212 alternately process the probability information of the second memory module 210. Referring to FIG. 3C, FIG. 3D and FIG. 4, since the probability information of the second memory module 210 corresponds to the second sub-matrix B with the regularly arranged sequence (all of the probability information are arranged on the two diagonals 312 and 314), the required memory positions provided to the first VNP module 204 or the CNP module 212 by the memory address storage module 214 is unnecessary for the second memory module 210, and just the related probability information corresponding to the second sub-matrix B that is processed by the first VNP module 204 or the CNP module 212 is required to be found, so as to facilitate executing the CNPs or the VNPs. However, the probability information of the first memory module 206 corresponds to the irregular first sub-matrix A, so that when the computation is switched between the first VNP module 204 and the CNP module 212, the memory address storage module 214 is required to provide the memory position required by the CNP module 212.

Generally, the identity matrices in the reordered and grouped first sub-matrix A, for example, the identity matrices S1, S2, S3 and S4 are reordered according to a sequence required by the computation of the first VNP module 204. Therefore, the memory units corresponding to the identity matrices S1 and S2 can be serially connected for a simultaneous VNP computation, and the memory units corresponding to the identity matrices S3 and S4 can be serially connected for a simultaneous VNP computation. However, when the first VNP module 204 is switched to the CNP module 212 for the CNP computation, check node orders or memory position accessing orders between the memory units of the identity matrices S1 and S2 are probably different, and check node orders or the memory position accessing orders between the memory units of the identity matrices S3 and S4 can also be different. In FIG. 3D, check node orders of the memory units of the identity matrices S1 and S2 are just the same, and the corresponding memory positions are accessed according to an order of i, ii, iii (i.e., memory addresses 1, 2 and 3). Regarding the check node order of the memory units of the identity matrix S3, the corresponding memory positions are accessed according to an order of ii, iii, i (i.e., memory addresses 2, 3 and 1), and regarding the check node order of the memory units of the identity matrix S4, the corresponding memory positions are accessed according to an order of iii, i, ii (i.e., memory addresses 3, 1 and 2).

Therefore, when the CNP module 212 executes the CNP, the memory address storage module 214 provides the required memory address to the CNP module 212. Since the first sub-matrix A is reordered and grouped, each sub-matrix has a characteristic of a cyclic identity matrix, so that just a start memory position is required to be provided to the CNP module 212. If the start memory position is not provided to the CNP module 212, a final result of the decoding process is definitely incorrect.

FIG. 5 is a flowchart illustrating a memory utilization method 500 of LDPC according to an exemplary embodiment of the invention. In the memory utilization method 500 of LDPC (which is referred to as a method 500 hereinafter), the memory units are grouped and are serially connected, which is also referred to as a folding memory for those skilled in the art. The method 500 is started from a step S502, and in the step S502, a number of memory units required for the computation of the parity check matrix H is determined, which is a total number of the memory units required for the VNPs and CNPs of the first sub-matrix A and the second sub-matrix B after the parity check matrix H is divided into the first sub-matrix A and the second sub-matrix B. Moreover, the first sub-matrix A is grouped into a plurality of randomly repeated pattern identity matrices, and a part of the required memory units is respectively one-to-one corresponding to the randomly repeated pattern identity matrices. After the step S502, a step S504 is executed.

In the step S504, VNPs or CNPs required to be executed at a same time stage are determined, and the VNPs or the CNPs executed at the same time stage are allocated in different VNP groups or different CNP groups. Referring to the embodiment of FIG. 3D and the former embodiments, the CNP module 212 has two processing units respectively in the memory units corresponding to the identity matrices S1, S2 and the identity matrices S3, S4, so that the CNPs can be executed in two time stages. To be more specific, at the first time stage, the first processing unit of the CNP module 212 executes the CNP to the memory unit of the matrix S1, and the second processing unit of the CNP module 212 simultaneously executes the CNP to the memory unit of the matrix S3. At the second time state, the first processing unit of the CNP module 212 executes the CNP to the memory unit of the matrix S2, and the second processing unit of the CNP module 212 simultaneously executes the CNP to the memory unit of the matrix S4. However, the invention is not limited thereto, and in another exemplary embodiment, the CNP module 212 can include more than two processing units, the first sub-matrix A can include more than four sub-matrices, and a number of the divided groups can be more than two. Moreover, the CNP module 212 can also sequentially process the probability information in the memory units of the same group during more than two time stages. After the step S504, a step S506 is executed.

In the step S506, a memory position accessing order of each memory unit is determined according to the VNPs or the CNPs executed at the same time stage. According to the memory position accessing order of the memory unit, the start memory position of the memory unit can be obtained, and after the memory units are serially connected, the start memory position of the memory unit can be stored in the memory address storage module 214 and will be provided to the first VNP module 204 or the CNP module 212 at a suitable time. After the step S506, a step S508 is executed.

In the step S508, a folding factor of the memory units is selected according to a desired data throughput. Generally, the data throughput can be measured according to a number of decoded LDPC bits within each frame duration, i.e., a unit of bits/second or bits/frame. Moreover, the more the soft decision cycles executed by the LDPC decoding process are, the more correct the decoding result is. However, each time one folding factor is added, the VNPs or the CNPs of the decoding computation require one more time stage, though the number of the required processing units is reduced, and meanwhile the routing complexity of the memory units is also further decreased. Therefore, in the step S508, a tradeoff is considered between the data throughput and the routibility depending on actual requirements of a wireless communication system. After the step S508, a step S510 is executed.

In the step S510, the memory units are serially connected as a plurality of parallel processing memory modules according to the folding factor and the allocated VNP groups or the allocated CNP groups. In other words, the memory units corresponding to the same allocated group are serially connected. After the memory units are serially connected, each parallel processing memory module just has a first memory unit including one input port set, and just has a last memory unit including one output port set. Moreover, each memory unit is configured for accessing one probability information, and each memory unit is accessed by the VNP and the CNP to complete one computation cycle, and only when the computation cycles of all of the memory units corresponding to the parity check matrix are completed, one decoding cycle of the decoding process is completed. After the step S510, the whole method 500 is completed. The invention is not limited to a sequence of the steps of FIG. 5, and a part of the steps can also be simultaneously executed. Moreover, the first memory module 206 and the second memory module 210 in the LDPC decoding apparatus of FIG. 2 can use the memory structure constructed according to the method 500. After the memory utilization method 500 of LDPC is introduced, an LDPC decoding method is described with reference of FIG. 2 and FIG. 6.

FIG. 6 is a flowchart illustrating an LDPC decoding method 600 according to an exemplary embodiment of the invention. Referring to FIG. 2 and FIG. 6, in the present exemplary embodiment, the LDPC decoding method 600 is started from a step S602, and in the step S602, the probability information corresponding to the first sub-matrix A of the parity check matrix H is temporarily stored in the first memory module 206, and meanwhile the probability information corresponding to the second sub-matrix B of the parity check matrix H is temporarily stored in the second memory module 210. Moreover, the first sub-matrix A is grouped into a plurality of randomly repeated pattern identity matrices. The first memory module 206 includes a plurality of memory units, and the memory units are respectively one-to-one corresponding to the randomly repeated pattern identity matrices. After the step S602, a step S604 is executed.

In the step S604, VNPs or CNPs are executed on the probability information in the first memory module 206 and the second memory module 210. After the step S604, a step S606 is executed. In the step S606, it is determined whether the probability information in the first memory module 206 and the second memory module 210 satisfies a decoding termination condition, i.e., whether the condition of the aforementioned equation (1) is satisfied. If the decoding termination condition is satisfied, after the step S606, a step S608 is executed. If the decoding termination condition is not satisfied, after the step S606, a step S610 is executed.

In the step S608, it is determined whether a predetermined time threshold is reached. Generally, the predetermined time threshold can be set as one frame duration, though the invention is not limited thereto, and the other suitable predetermined time thresholds can also be used depending on actual requirements of the wireless communication system. If the predetermined time threshold is reached, after the step S608, the step S610 is executed, and if the predetermined time threshold is not reached, after the step S608, the step S604 is repeated. In the step S610, the probability information of the first memory module 206 is converted into an LDPC output data through a hard decision, and the LDPC output data is reordered in the second memory module 210. Namely, the second memory module 210 reorders the LDPC output data converted from the probability information of the first memory module 206. Then, the reordered LDPC output data is output to a next stage, for example, a source decoding stage. After the step S610, the LDPC decoding method 600 is completed. It should be noted that the invention is not limited to a sequence of the steps of FIG. 6, and a part of the steps can also be simultaneously executed.

FIG. 7 is a system block diagram illustrating another LDPC decoding apparatus 700 according to another exemplary embodiment of the invention. The LDPC decoding apparatus 700 is similar to the LDPC decoding apparatus 200 of FIG. 2, though the LDPC decoding apparatus 700 includes a first dealer network unit 742, a second dealer network unit 744, a third dealer network unit 746 and a fourth dealer network unit 748. The first dealer network unit 742 and the second dealer network unit 744 are respectively coupled between the first VNP module 204 and the first memory module 206. The third dealer network unit 746 and the fourth dealer network unit 748 are respectively coupled between the second VNP module 208 and the second memory module 210. The first dealer network unit 742, the second dealer network unit 744, the third dealer network unit 746 and the fourth dealer network unit 748 in the LDPC decoding apparatus 700 are configured to collaborate different code rates. For example, in the DVB-S2 standard, the LDPC decoding apparatus is required to process the LDPC codes with about eleven different code rates, and the parity check matrices respectively corresponding to the code rates are different. If there is none suitable approach between the first VNP module 204 and the first memory module 206 or between the second VNP module 208 and the second memory module 210 for adjusting reading/writing of the probability information, the code rate variation can cause an incorrect LDPC decoding result.

In the exemplary embodiment, the first dealer network unit 742, the second dealer network unit 744, the third dealer network unit 746 and the fourth dealer network unit 748 can be respectively implemented by a multiplexer, though the invention is not limited thereto, and in other exemplary embodiments of the invention, the first dealer network unit 742, the second dealer network unit 744, the third dealer network unit 746 and the fourth dealer network unit 748 can be respectively implemented by other approaches. Moreover, the first memory module 206 and the second memory module 210 in the LDPC decoding apparatus 700 of FIG. 7 can use the memory structure constructed according to the method 500.

In summary, the exemplary embodiments of the invention provide a memory utilization method of LDPC, an LDPC decoding method and a decoding apparatus thereof. The memory utilization method of LDPC is used in the LDPC decoding process, by which the parity check matrix required by the LDPC decoding process can be divided into a first sub-matrix and a second sub-matrix. The first memory module corresponding to the first sub-matrix applies a modified partially parallel memory structure, and a plurality of memory units therein are suitably grouped and serially connected, so as to simultaneously reduce an occupation area of the memory device and extra overhead, and lower a routing complexity among the memory units and between the memory units and the other peripheral devices. Moreover, the second memory module corresponding to the second sub-matrix is configured to execute the decoding computation or reorder the decoding result of the probability information of the first memory module in different time stages, so as to improve memory utilization efficiency.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A memory utilization method of low density parity check code (LDPC), adapted to a decoding process in a wireless receiver, comprising:
determining one or a plurality of variable node processes (VNPs) or one or a plurality of check node processes (CNPs) required to be executed at a same time stage in the decoding process;
allocating the VNPs or the CNPs executed at the same time stage in different VNP groups or different CNP groups;
determining a folding factor of memory units according to a desired data throughput; and
serially connecting the memory units as a plurality of parallel processing memory modules according to the folding factor and the allocated VNP groups or the allocated CNP groups.

2. The memory utilization method of LDPC as claimed in claim 1, further comprising:
determining a total number of the memory units required by computation of a parity check matrix in the decoding process; and
determining a memory position accessing order of each of the memory units according to the VNPs or the CNPs executed at the same time stage.

3. The memory utilization method of LDPC as claimed in claim 1, wherein each of the parallel processing memory modules has one first memory unit having an input port set, and one last memory unit having an output port set.

4. The memory utilization method of LDPC as claimed in claim 2, wherein the step of determining the total number of the memory units required by the computation of the parity check matrix further comprises:
converting the parity check matrix into a quasi-cyclic (QC) matrix;
dividing the QC matrix into a first sub-matrix and a second sub-matrix, wherein the second sub-matrix is a square matrix having two diagonals, and the two diagonals both have values of “1”; and
grouping the first sub-matrix into a plurality of randomly repeated pattern identity matrices, wherein a part of the memory units is respectively one-to-one corresponding to the randomly repeated pattern identity matrices.

5. The memory utilization method of LDPC as claimed in claim 2, wherein the greater a value of the folding factor is, the more memory units each of the parallel processing memory module comprises, the lower routing complexity of the memory units is, and the lower an actual data throughput is.

6. The memory utilization method of LDPC as claimed in claim 1, wherein each of the memory units is configured for accessing a probability information, each of the memory units is accessed by the VNP or the CNP to execute a computation cycle, and after the computation cycle is completed in each of the memory units corresponding to the parity check matrix, the decoding process completes a decoding cycle.

7. A low density parity check code (LDPC) decoding method, adapted to a decoding process in a wireless receiver, comprising:
executing a variable node process (VNP) or a check node process (CNP) on probability information in a first memory module and a second memory module;
determining whether the probability information in the first memory module and the second memory module satisfies a decoding termination condition;
converting the probability information of the first memory module into an LDPC output data through a hard decision, and reordering the LDPC output data in the second memory module.

8. The LDPC decoding method as claimed in claim 7, wherein during the decoding process, a parity check matrix is used to associate with the VNP or the CNP, and the LDPC decoding method further comprises:
dividing the parity check matrix into a first sub-matrix and a second sub-matrix; and
respectively storing probability information corresponding to the first sub-matrix and probability information corresponding to the second sub-matrix into the first memory module and the second memory module.

9. The LDPC decoding method as claimed in claim 7, wherein the decoding termination condition is that the probability information in the first memory module and the second memory module satisfies a condition of a following equation (1):
νH^{T}=0 equation (1)
where ν is a vector, which represents a received LDPC input, or an LDPC codeword received through a wireless transmission, and H^{T} represents a transpose matrix of the parity check matrix H that is required in the decoding process.

10. The LDPC decoding method as claimed in claim 7, further comprising:
determining whether a predetermined time threshold is reached, wherein if the predetermined time threshold is not reached, the step of executing the VNP or the CNP on the probability information in the first memory module and the second memory module is repeated; and
if the predetermined time threshold is reached, the probability information of the first memory module is converted into the LDPC output data through the hard decision, and the LDPC output data is reordered in the second memory module.

11. The LDPC decoding method as claimed in claim 10, wherein the predetermined time threshold is a frame duration.

12. The LDPC decoding method as claimed in claim 7, further comprising:
executing the VNP and the CNP on all probability information in the first memory module and the second memory module within a computation cycle;
after the VNP is executed on the probability information in the first memory module, storing a first computation result of the VNP to the first memory module, and executing the CNP; and
after the VNP is executed on the probability information in the second memory module, storing a second computation result of the VNP to the second memory module, and executing the CNP.

13. The LDPC decoding method as claimed in claim 8, wherein after the step of dividing the parity check matrix into the first sub-matrix and the second sub-matrix, the LDPC decoding method further comprises:
grouping the first sub-matrix into a plurality of randomly repeated pattern identity matrices, wherein the first memory module comprises a plurality of memory units respectively one-to-one corresponding to the randomly repeated pattern identity matrices.

14. The LDPC decoding method as claimed in claim 7, wherein the second sub-matrix is an identity matrix comprising two diagonals with values of “1”, and there is a fixed offset between the two diagonals.

15. The LDPC decoding method as claimed in claim 7, wherein a plurality of memory units of the first memory module have a partially parallel processing structure.

16. A low density parity check code (LDPC) decoding apparatus, adapted to a decoding process in a wireless receiver, comprising:
a variable node process (VNP) module, configured for executing a VNP on probability information in a first memory module and a second memory module;
a check node process (CNP) module, configured for executing a CNP on the probability information in the first memory module and the second memory module;
a computation termination determination module, configured for determining whether the probability information in the first memory module and the second memory module satisfies a decoding termination condition; and
a slicer, configured for converting the probability information of the first memory module into an LDPC output data through a hard decision, and reordering the LDPC output data through the second memory module.

17. The LDPC decoding apparatus as claimed in claim 16, wherein when an LDPC is decoded, a parity check matrix is used to associate with the VNP or the CNP.

18. The LDPC decoding apparatus as claimed in claim 17, wherein the decoding termination condition is that the probability information in the first memory module and the second memory module satisfies a condition of a following equation (1):
νH^{T}=0 equation (1)
where ν is a vector, which represents a received LDPC input, or an LDPC codeword received through a wireless transmission, and H^{T} represents a transpose matrix of a parity check matrix H that is required when the LDPC is decoded.

19. The LDPC decoding apparatus as claimed in claim 17, further comprising:
a control module, configured for determining whether a predetermined time threshold is reached, wherein
if the predetermined time threshold is not reached, the control module notifies the VNP module and the CNP module to continually execute the VNP or the CNP on the probability information in the first memory module and the second memory module; and
if the predetermined time threshold is reached, the control module notifies the slicer to convert the probability information of the first memory module into the LDPC output data through the hard decision, and reorder the LDPC output data in the second memory module.

20. The LDPC decoding apparatus as claimed in claim 19, wherein the predetermined time threshold is a frame duration.

21. The LDPC decoding apparatus as claimed in claim 17, wherein
within a computation cycle, the VNP module and the CNP module execute the VNP and the CNP on all probability information in the first memory module and the second memory module;
after the VNP module executes the VNP on the probability information in the first memory module, the VNP module stores a first computation result of the VNP to the first memory module, and then the CNP module executes the CNP; and
after the VNP module executes the VNP on the probability information in the second memory module, the VNP module stores a second computation result of the VNP to the second memory module, and then the CNP module executes the CNP.

22. The LDPC decoding apparatus as claimed in claim 17, further comprising:
a matrix converting unit, configured for dividing the parity check matrix into a first sub-matrix and a second sub-matrix, and grouping the first sub-matrix into a plurality of randomly repeated pattern identity matrices, wherein
the VNP module and the CNP module respectively stores the probability information corresponding to the first sub-matrix and the probability information corresponding to the second sub-matrix into the first memory module and the second memory module, wherein the first memory module comprises a plurality of memory units respectively one-to-one corresponding to the randomly repeated pattern identity matrices.

23. The LDPC decoding apparatus as claimed in claim 17, wherein the second sub-matrix is an identity matrix comprising two diagonals with values of “1”, and there is a fixed offset between the two diagonals.

24. The LDPC decoding apparatus as claimed in claim 17, further comprising:
a memory address storage module, configured for providing a start memory position of each memory unit in the first memory module to the CNP module when the CNP module executes the CNP on the probability information in the first memory module, wherein memory position accessing orders respectively of the memory units are different.

25. The LDPC decoding apparatus as claimed in claim 17, wherein a plurality of memory units of the first memory module have a partially parallel processing structure, wherein the first memory module comprises a plurality of parallel processing memory modules and the memory units of the first memory module are connected serially as parallel processing memory modules.

26. The LDPC decoding apparatus as claimed in claim 16, wherein in each parallel processing memory module of the first memory module, just a first memory unit comprises an input port set, and just a last memory unit comprises an output port set.
